(19) United States
(12) Patent Application Publication
(10) Pub. No.: US 2025/0244119 A1
(43) Pub. Date: Jul. 31, 2025

(54) POSITION DETECTION DEVICE

(71) Applicant: Proterial, Ltd., Tokyo (JP)

(72) Inventors: Yohei SHIRAKAWA, Tokyo (JP); Yuta SUGIYAMA, Tokyo (JP)

(73) Assignee: Proterial, Ltd., Tokyo (JP)

(21) Appl. No.: 19/022,166

(22) Filed: Jan. 15, 2025

(30) Foreign Application Priority Data
Jan. 31, 2024 (JP) 2024-013185

(51) Int. Cl. G01B 7/00; B62D 15/02; G01R 33/00

(52) U.S. Cl. CPC G01B 7/003; B62D 15/0225; G01R 33/0005

(57) ABSTRACT

A position detection device configured to detect a position of a shaft made of metal that moves forward and backward in an axial direction within a predetermined range includes an excitation coil that generates an alternating magnetic field, a target that moves integrally with the shaft and in which a magnetic flux of the alternating magnetic field is interlinked, and a detection coil having a detection portion that faces the target while the shaft moves from one axial moving end to the other axial moving end. An induced voltage induced in the detection portion by the magnetic flux of the alternating magnetic field varies with a position of the target relative to the detection portion, and the detection coil has adjustment portions that suppress an effect of an inclination of the shaft with respect to the detection portion on the induced voltage induced in the detection portion.

### CROSS-REFERENCE TO RELATED APPLICATIONS

The present application is based on Japanese patent application No. 2024-013185 filed on Jan. 31, 2024, the entire contents of which are incorporated herein by reference.

### TECHNICAL FIELD

The present invention relates to a position detection device for detecting the position of a shaft that moves forward and backward in the axial direction.

### BACKGROUND OF THE INVENTION

Conventionally, a position detection device that detects the position of a shaft that moves forward and backward in the axial direction is being used, for example, to detect the position of a rack shaft in a steering device of a vehicle.

The detection unit described in Patent Literature 1 detects an axial position of a rack shaft of an electric power steering device and includes a DC power supply, a permanent magnet, an element group composed of first to fourth magnetoresistive elements disposed between the permanent magnet and the rack shaft, and a calculation unit for calculating the position of the rack shaft. In the element group, a series circuit including the first and second magnetoresistive elements being connected in series, and a series circuit including the third and fourth magnetoresistive elements being connected in series are connected in parallel to form a bridge circuit. The potential of a first terminal connected between the first and second magnetoresistive elements and a potential of a second terminal connected between the third and fourth magnetoresistive elements are input to the calculation unit. A plurality of grooves extending in a direction inclined with respect to the axial direction of the rack shaft is formed on the surface of the rack shaft facing the element group.

In the detection unit configured as described above, when the rack shaft moves in the axial direction due to the rotation of the pinion gear shaft meshing with the rack shaft and the relative positions of the first to fourth magnetoresistive elements with respect to the grooves change, the balance of electrical resistance of the first to fourth magnetoresistive elements changes, so that the potentials of the first terminal and the second terminal change. The calculation unit calculates the position of the rack shaft based on changes in these potentials.
Citation List Patent Literature 1: WO2021/210125

### SUMMARY OF THE INVENTION

In the detection unit described in Patent Literature 1, if the rack shaft is inclined with respect to the vehicle width direction due to, for example, vibrations caused by vehicle running or the like, the distance between the first to fourth magnetoresistive elements and the rack shaft changes and an error occurs in the detection position of the rack shaft.

Accordingly, it is an object of the present invention to provide a position detection device capable of detecting the position of the rack shaft that moves forward and backward in the axial direction with high accuracy.

To solve the problems mentioned above, the present invention provides a position detection device for detecting a position of a shaft made of metal that moves forward and backward in an axial direction within a predetermined range, comprising:
an excitation coil that generates an alternating magnetic field;
a target that moves integrally with the shaft and in which a magnetic flux of the alternating magnetic field is interlinked; and
a detection coil having a detection portion that faces the target while the shaft moves from one axial moving end to an other axial moving end,
wherein an induced voltage induced in the detection portion by the magnetic flux of the alternating magnetic field varies with a position of the target relative to the detection portion, and
wherein the detection coil has adjustment portions that suppress an effect of an inclination of the shaft with respect to the detection portion on the induced voltage induced in the detection portion.

### Advantageous Effects of the Invention

According to a position detection device of the present invention, it is possible to detect the position of a shaft that moves forward and backward in the axial direction with high accuracy.

### BRIEF DESCRIPTION OF DRAWINGS

FIG. 1 is a schematic diagram of a vehicle equipped with a steer-by-wire steering device having a stroke sensor as a position detection device according to the first embodiment of the present invention.

FIG. 2 is a cross-sectional view of a rack shaft, a housing, a target, and a substrate taken along line A-A in FIG. 1.

FIG. 3 is a perspective view showing the rack shaft, the housing, the target, and the substrate.

FIGS. 4A to 4D are explanatory diagrams showing wiring patterns of a first wiring layer, a second wiring layer, a third wiring layer, and a fourth wiring layer of the substrate.

FIG. 5A is an explanatory diagram showing the wiring pattern of the first wiring layer and the wiring pattern of the third wiring layer overlaid on each other.

FIG. 5B is an explanatory diagram showing the wiring pattern of the second wiring layer and the wiring pattern of the fourth wiring layer overlaid on each other.

FIG. 6 is an explanatory diagram showing the wiring patterns of the first, second, third, and fourth wiring layers overlaid on each other.

FIG. 7 is a graph showing an example of the relationship between a supply voltage supplied from a power supply unit to an excitation coil and an induced voltage induced in a first detection coil and a second detection coil.

FIG. 8 is a graph showing the relationship between the peak voltage, which is a peak value of the induced voltage induced in the first detection coil, and the position of the target.

FIG. 9 is a graph showing the relationship between the peak voltage, which is a peak value of the induced voltage induced in the cosine wave-shaped detection coil, and the position of the target.

FIG. 10A is an explanatory diagram schematically showing the relationship between the inclination of the rack shaft with respect to the substrate and the effect of the inclination of the rack shaft on the magnetic flux density interlinked with the first detection coil.

FIG. 10B is an explanatory diagram schematically showing the relationship between the inclination of the rack shaft with respect to the substrate and the effect of the inclination of the rack shaft on the magnetic flux density interlinked with the second detection coil.

FIG. 11 is a graph showing increments in detection error of the position of the target due to the inclination of the rack shaft with respect to the substrate for the case where the first detection coil has an adjustment portion and the case where the first detection coil does not have an adjustment portion.

FIGS. 12A to 12D are explanatory diagrams showing the wiring patterns of the first to fourth wiring layers of the substrate on which the adjustment portions in a first modified example are formed.

FIG. 13 is an explanatory diagram showing the wiring patterns of the first to fourth wiring layers overlaid on each other of the substrate on which the adjustment portions in the first modified example are formed.

FIGS. 14A to 14D are explanatory diagrams showing the wiring patterns of the first to fourth wiring layers of the substrate on which the adjustment portions in a second modified example are formed.

FIG. 15 is an explanatory diagram showing the wiring patterns of the first to fourth wiring layers overlaid on each other of the substrate on which the adjustment portions in the second modified example are formed.

### DETAILED DESCRIPTION OF THE INVENTION

### Embodiment

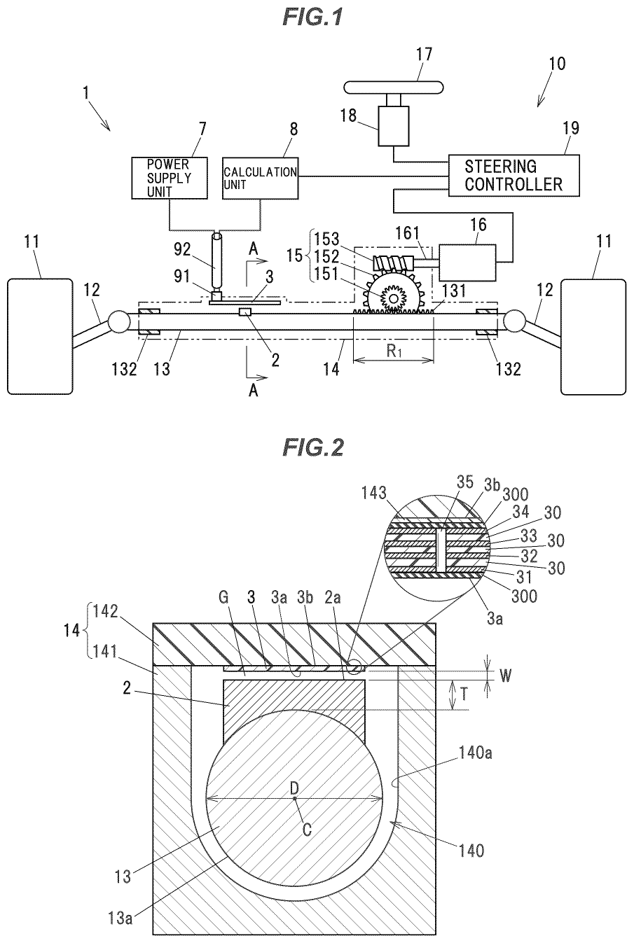

FIG. 1 is a schematic diagram of a vehicle equipped with a steer-by-wire steering device 10 with a stroke sensor 1 as a position detection device in the first embodiment of the present invention.

As shown in FIG. 1, the steering device 10 comprises a stroke sensor 1, tie rods 12 connected to the steerable wheels 11 (right and left front wheels), a rack shaft 13 connected to the tie rods 12, a cylindrical housing 14 for accommodating the rack shaft 13, a worm reduction mechanism 15 having a pinion gear 151 meshed with rack teeth 131 of the rack shaft 13, an electric motor 16 that applies a moving force to the rack shaft 13 via the worm reduction mechanism 15, a steering wheel 17 to be operated by the driver, a steering angle sensor 18 that for detecting the steering angle of the steering wheel 17, and a steering controller 19 for controlling the electric motor 16 based on the steering angle detected by the steering angle sensor 18.

In FIG. 1, the housing 14 is shown in a virtual line. The rack shaft 13 is made of a steel material such as carbon steel, and is supported by a pair of rack bushings 132 attached to both ends of the housing 14. The worm reduction mechanism 15 has a worm wheel 152 and a worm gear 153, and a pinion gear 151 is attached to the worm wheel 152. The worm gear 153 is attached to a motor shaft 161 of the electric motor 16.

The electric motor 16 generates torque by a motor current supplied from the steering controller 19 and rotates the worm wheel 152 and the pinion gear 151 via the worm gear 153. When the pinion gear 151 rotates, the rack shaft 13 moves forward and backward in the vehicle width direction to steer the left and right steerable wheels 11. The rack shaft 13 can move rightward and leftward in the vehicle width direction within a predetermined range from the neutral position when the steering angle is zero. In FIG. 1, a double arrow indicates a range R₁ where the rack shaft 13 can move in the vehicle width direction.

### (Configuration of Stroke Sensor 1)

The stroke sensor 1 has a target (i.e., an object to be detected, detection target) 2 fixed to the rack shaft 13, a substrate 3 arranged in parallel with the rack shaft 13 to face the target 2, a power supply unit 7, and a calculation unit 8. The substrate 3 is connected to the power supply unit 7 and the calculation unit 8 by a connector 91 and a cable 92 attached to the substrate 3. The substrate 3 is fixed in the housing 14, parallel to the rack shaft 13. The stroke sensor 1 detects the position of the rack shaft 13 with respect to the housing 14 by the position of the target 2 and outputs information on the detected position to the steering controller 19. The steering controller 19 controls the electric motor 16 in such a manner that the position of the rack shaft 13 detected by the stroke sensor 1 corresponds to the steering angle of the steering wheel 17 detected by the steering angle sensor 18.

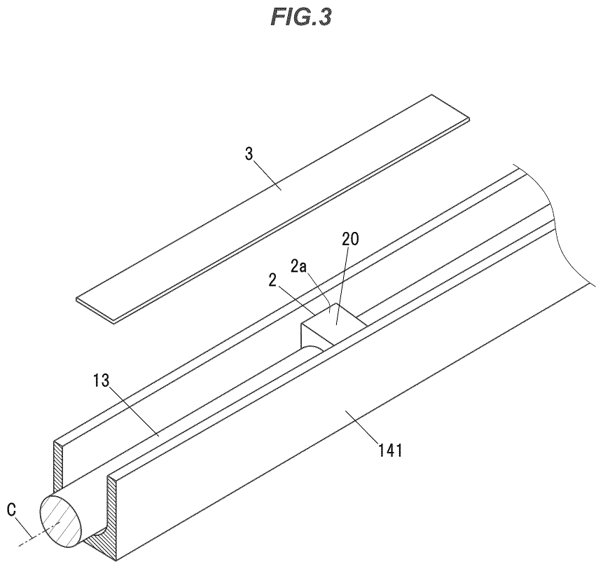

FIG. 2 is a cross-sectional view of the rack shaft 13, the housing 14, the target 2, and the substrate 3 taken along line A-A in FIG. 1. FIG. 3 is a perspective view showing the rack shaft 13, the main body 141 of the housing 14, the target 2, and the substrate 3. In FIG. 3, the center axis line C of the rack shaft 13 is indicated by a dash-dot line. The rack shaft 13 moves along the central axis line C by the moving force applied by the electric motor 16.

The rack shaft 13 is a rod-shaped body made of steel with a circular cross-section. The housing 14 has the main body 141 made of metal and a lid 142 made of resin, and the lid 142 is attached to the main body 141 by, for example, adhesion. The main body 141 has a U-shaped cross-section in which an accommodation space 140 for accommodating the rack shaft 13 is formed, and the accommodation space 140 opens upward in the vertical direction. A diameter D of the rack shaft 13 is, for example, 25 mm.

A gap of 1 mm or more, for example, is formed between an outer peripheral surface 13a of the rack shaft 13 and an inner surface 140a of the accommodation space 140. The lid 142 is formed in a flat plate shape and covers the accommodation space 140 from above in the vertical direction. The main body 141 is a non-magnetic material made of die-cast aluminum alloy, for example. The material of the lid 142 is not necessarily limited to resin, but it is desirable to use a non-magnetic and non-conductive material.

The target 2 is fixed to the rack shaft 13 so that it protrudes from the outer peripheral surface 13a of the rack shaft 13 toward the substrate 3 and moves integrally with the rack shaft 13. Fixing of the target 2 to the rack shaft 13 can be done by fixing means such as adhesion or welding, for example. The target 2 is made of a material with higher magnetic permeability than that of the rack shaft 13 or a material with higher electrical conductivity than that of the rack shaft 13. When a material with higher magnetic permeability than that of the rack shaft 13 is used as the material of the target 2, it is desirable to use a magnetic material such as ferrite, which has high electrical resistance and is less likely to generate eddy currents. When a material with higher conductivity than that of the rack shaft 13 is used for the target 2, a metal mainly composed of aluminum or copper, for example, may be used as the material.

In the present embodiment, the target 2 protrudes from the outer peripheral surface 13a of the rack shaft 13 toward the substrate 3. Therefore, even if a material with equal magnetic permeability to the rack shaft 13 or a material with equal electrical conductivity to the rack shaft 13 is used as the material for the target 2, the same actions and effects described below can be obtained. However, in order to increase the accuracy of position detection, it is desirable to use a high permeability material with a higher magnetic permeability than the material of rack shaft 13 or a high conductivity material with a higher conductivity than the material of rack shaft 13 as the material of the target 2.

A facing surface 2a of the target 2 facing the substrate 3 is formed in flat shape and disposed in parallel to a front surface 3a of the substrate 3 via an air gap G. A back surface 3b of the substrate 3 is fixed to the lid 142 by an adhesive 143. The shape of the facing surface 2a of the target 2, viewed from the substrate 3 side, is a rectangular shape. The width W of the air gap G is, for example, 1 mm. A minimum thickness T of the target 2 in the direction perpendicular to the facing surface 2a is, for example, 3 mm. Furthermore, in the present embodiment, the rack shaft 13 is formed to have a circular cross-section, but the cross-section of the rack shaft 13 is not limited to a circle but may be in a D-shape in which a part is formed in a straight line or in a polygonal shape.

The substrate 3 is a four-layer substrate having a first wiring layer 31, a second wiring layer 32, a third wiring layer 33, and a fourth wiring layer 34. The first wiring layer 31 and the fourth wiring layer 34 are the outer layers of the substrate 3, while the second wiring layer 32 and the third wiring layer 33 are the inner layers of the substrate 3. A base material 30 made of a dielectric material such as FR4 (glass fiber impregnated with epoxy resin and heat-cured) is placed between the first wiring layer 31 and the second wiring layer 32, between the second wiring layer 32 and the third wiring layer 33, and between the third wiring layer 33 and the fourth wiring layer 34. The first wiring layer 31 and the fourth wiring layer 34 are covered with a resist film 300 having electrical insulation properties. A wiring pattern is formed in the first wiring layer 31, the second wiring layer 32, the third wiring layer 33, and the fourth wiring layer 34, and the wiring patterns of these layers are connected by a via 305 at multiple locations on the substrate 3. The substrate 3 has a flat rectangular shape whose longitudinal direction is the axial direction of the rack shaft 13.

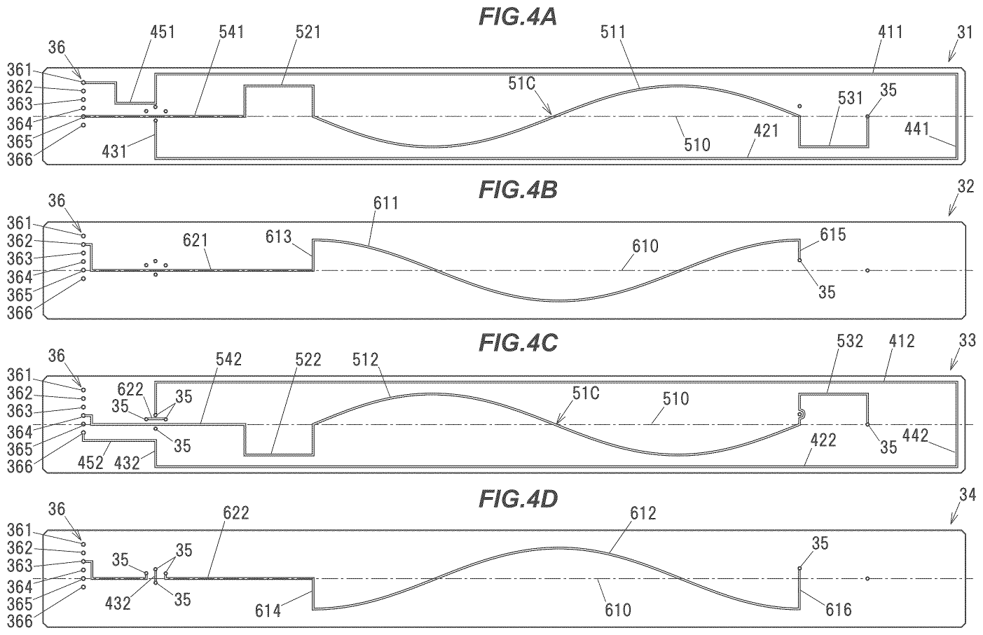

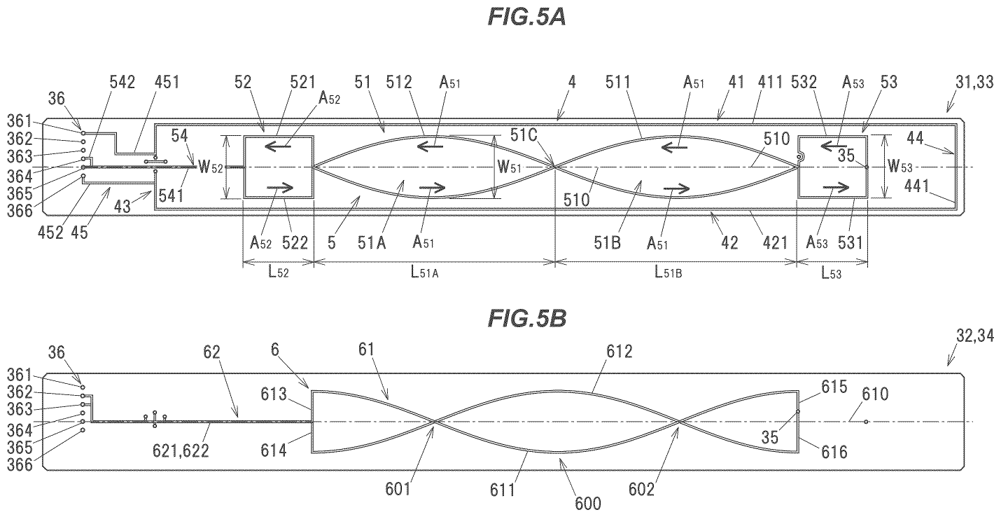

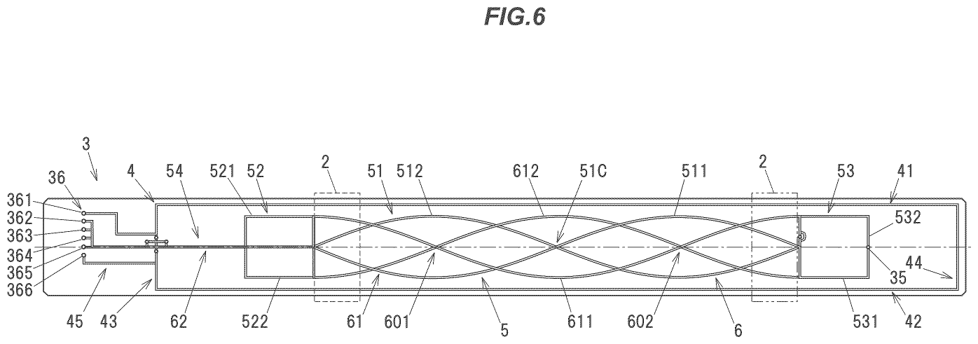

Next, the wiring configuration of the substrate 3 will be described in detail with reference to FIGS. 4A to 6. FIGS. 4A to 4D are explanatory diagrams showing wiring patterns of a first wiring layer 31, a second wiring layer 32, a third wiring layer 33, and a fourth wiring layer 34, viewed from the front surface 3a side. FIG. 5A is an explanatory diagram showing the wiring pattern of the first wiring layer 31 shown in FIG. 4A and the wiring pattern of the third wiring layer 33 shown in FIG. 4C that are overlaid on each other. FIG. 5B is an explanatory diagram showing the wiring pattern of the second wiring layer 32 shown in FIG. 4B and the wiring pattern of the fourth wiring layer 34 shown in FIG. 4D that are overlaid on each other. FIG. 6 is an explanatory diagram showing the wiring patterns of the first wiring layer 31, the second wiring layer 32, the third wiring layer 33, and the fourth wiring layer 34 shown in FIGS. 4A to 4D that are overlaid on each other. In FIGS. 5A, 5B and 6, the wiring patterns of the third wiring layer 33 and the fourth wiring layer 34 are shown in gray. The wiring patterns shown in FIGS. 4A to 6 are merely examples, and various wiring patterns may be used as long as the substrate 3 is formed so as to obtain the effects of the present invention.

On the substrate 3, an excitation coil 4 that generates an alternating magnetic field (AC magnetic field) and a first detection coil 5 and a second detection coil 6 in which the magnetic flux of the alternating magnetic field generated by the excitation coil 4 is interlinked, are formed by wiring patterns. The excitation coil 4 is formed over the first wiring layer 31 and the third wiring layer 33. The first detection coil 5 is formed over the first wiring layer 31 and the third wiring layer 33, and the second detection coil 6 is formed over the second wiring layer 32 and the fourth wiring layer 34. The first detection coil 5 corresponds to the “detection coil” of the invention described in the claims.

The excitation coil 4, the first detection coil 5, and the second detection coil 6 extend in the longitudinal direction of the substrate 3 along the axial direction of the rack shaft 13. At one end of the substrate 3 in the longitudinal direction, an input/output section 36 is formed having first to sixth through-hole lands 361 to 366 through which a plurality of connector pins of the connector 91 shown in FIG. 1 are inserted. Hereinafter, of both sides of the substrate 3 in the longitudinal direction, the side on which the input/output section 36 is formed is hereinafter referred to as the one side in the longitudinal direction, and the opposite side is referred to as the other side in the longitudinal direction.

### (Configuration of Excitation Coil 4)

The excitation coil 4 has a rectangular shape having a pair of long side portions 41 and 42 extending in the axial direction of the rack shaft 13, a pair of short side portions 43 and 44 between the pair of long side portions 41 and 42, and a connection line portion 45 between the short side portion 43 on one side in the longitudinal direction and the input/output section 36 of the pair of short side portions 43, 44. The long side portions 41, 42 of the excitation coil 4 are formed by conductor lines 411, 421 formed in the first wiring layer 31 and conductor lines 412, 422 formed in the third wiring layer 33. The short side portions 43, 44 of the excitation coil 4 are formed by the conductor lines 431, 441 formed in the first wiring layer 31 and the conductor lines 432, 442 formed in the third wiring layer 33. The connection line portion 45 is formed by a conductor line 451 formed in the first wiring layer 31 and a conductor line 452 formed in the third wiring layer 33. The conductor line 451 of the connection line portion 45 is connected to the first through-hole land 361 of the input/output section 36, and the conductor line 452 is connected to the sixth through-hole land 366.

The first detection coil 5 and the second detection coil 6 are formed inside the pair of long side portions 41, 42 and a pair of short side portions 43, 44 of the rectangular-shaped excitation coil 4. The excitation coil 4 is supplied with an alternating current from the power supply unit 7 through the connector 91 and the cable 92. The excitation coil 4 generates an alternating magnetic field with a frequency corresponding to the frequency of the AC current. The magnetic flux of the alternating magnetic field generated by the excitation coil 4 is interlinked with the first detection coil 5 and the second detection coil 6, and an induced voltage corresponding to the frequency of the alternating magnetic field is generated.

The magnetic flux of the alternating magnetic field generated by the excitation coil 4 is also interlinked with the target 2. The magnetic fluxes interlinked with the target 2 affect the intensity distribution of the magnetic flux interlinked with the first detection coil 5 and the second detection coil 6, and the magnitude of the induced voltage generated in the first detection coil 5 and the second detection coil 6 by the alternating magnetic field generated by the excitation coil 4 varies depending on the position of the target 2. In FIG. 6, the position of the target 2 when the rack shaft 13 is at one axial moving end is shown by a dashed line, and the position of the target 2 when the rack shaft 13 is at the other axial moving end is shown by a double-dashed line.

The phases of the voltages induced in each of the first detection coil 5 and the second detection coil 6 changing depending on the position of the target 2 during the movement of the rack shaft 13 from one axial moving end to the other axial moving end are different from each other. In the present embodiment, the phase of the change in the magnitude of the induced voltage induced in the first detection coil 5 and the second detection coil 6 during the movement of the rack shaft 13 from one axial moving end to the other axial moving end differ by 90°.

### (Configuration of the First Detection Coil 5)

The first detection coil 5 has a detection portion 51 facing the target 2 while the rack shaft 13 moves from one axial moving end to the other axial moving end, two adjustment portions 52, 53 on both sides of the detection portion 51 in the longitudinal direction of the substrate 3, and a connection line portion 54 for connection with the input/output section 36. The adjustment portions 52, 53 suppress the influence of the inclination of the rack shaft 13 with respect to the substrate 3 and the detection portion 51 on the induced voltage induced in the detection portion 51. The action and effect of the adjustment portions 52, 53 are described below.

The detection portion 51 has a shape that combines a pair of curved portions 511 and 512. In the examples shown in FIGS. 4A to 6, the curved portions 511 are formed in the first wiring layer 31 and the curved portions 512 are formed in the third wiring layer 33. The curved portions 511 and 512 are sinusoidal (sine wave-shaped) conductor lines that are symmetrical in the width direction of the substrate 3 across a symmetry axis line 510 that extends in the longitudinal direction of the substrate 3 and the detection portion 51. More specifically, the shape of the curved portion 511 in the first wiring layer 31 viewed from the normal direction of the substrate 3 is a sine wave shape from −180° to 180° when the symmetry axis line 510 is regarded as the phase axis, as shown in FIG. 4A, and the shape of the curved portion 512 is a sine wave shape from 0° to 360° when the symmetry axis line 510 is regarded as the phase axis as shown in FIG. 4C.

As shown in FIG. 5A, one curved portion 511 and the other curved portion 512, which constitute the detection portion 51, cross each other without touching (short-circuiting) at a center portion 51C in the longitudinal direction in the detection portion 51. The curved portions 511, 512 are close to each other toward the symmetry axis line 510 at both ends in the longitudinal direction in the detection portion 51, and the spacing between these two ends and the center portion 51C is wider.

The respective shapes of the adjustment portions 52, 53 viewed from the normal direction of the substrate 3 are rectangular. The adjustment portion 52 provided on one side in the longitudinal direction of the detection portion 51 is composed of a conductor line 521 formed in the first wiring layer 31 continuous with the end portion on one side in the longitudinal direction in the curved portion 511 constituting the detection portion 51 and a conductor line 522 formed in the third wiring layer 33 continuous with the end portion on one side in the longitudinal direction in the curved portion 512 constituting the detection portion 51. The conductor line 522 formed in the third wiring layer 33 continuous with the end portion on one side in the longitudinal direction in the curved portion 512 constituting the detection portion 51. The adjustment portion 53 provided on the other side in the longitudinal direction of the detection portion 51 is composed of a conductor line 531 formed in the first wiring layer 31 continuous with the end portion on the other side in the longitudinal direction in the curved portion 511 constituting the detection portion 51 and a conductor line 532 formed in the third wiring layer 33 continuous with the end portion on the other side in the longitudinal direction in the curved portion 512 constituting the detection portion 51. The conductor line 531 and the conductor line 532 are connected by a via 35 at the other end in the longitudinal direction in the adjustment portion 53.

The connection line portion 54 connects the adjustment portion 52 and the input/output section 36 on one side in the longitudinal direction. In the present embodiment, the conductor line 541 connecting the end portion on one side in the longitudinal direction in the conductor line 521 of the adjustment portion 52 to the fifth through-hole land 365, and the conductor line 542 connecting the end portion on one side in the longitudinal direction in the conductor line 522 of the adjustment portion 52 to the fourth through-hole land 364, constitute the connection line portion 54. The conductor line 541 is formed in the first wiring layer 31 along the symmetry axis line 510. The conductor line 542 is formed in the third wiring layer 33 along the symmetry axis line 510.

When the shortitudinal direction perpendicular to the longitudinal direction of the substrate 3 is the width direction, in the curved portion 511 constituting the detection portion 51, the portion on one side in the longitudinal direction than the center portion 51C is provided on one side of the symmetry axis line 510 in the width direction (lower side in the drawing), while the portion on the other side in the longitudinal direction than the center portion 51C is provided on the other side of the symmetry axis line 510 in the width direction (upper side in the drawing). The conductor line 521 of the adjustment portion 52, which is formed continuously at the end portion of one side in the longitudinal direction of the curved portion 511, is provided on the other side in the width direction of the symmetry axis line 510 (upper side in the drawing), and the conductor line 531 of the adjustment portion 53, which is formed continuously at the end portion on the other side in the longitudinal direction of the curved portion 511, is provided on one side in the width direction of the symmetry axis line 510 (lower side in the drawing).

In the curved portion 512, which together with the curved portion 511 constitutes the detection portion 51, the portion on one side in the longitudinal direction than the center portion 51C is provided on the other side in the width direction of the symmetry axis line 510 (upper side in the drawing), while the portion on the other side in the longitudinal direction than the center portion 51C is provided on the other side in the width direction of the symmetry axis line 510 (lower side in the drawing). The conductor line 522 of the adjustment portion 52, which is formed continuously with the end portion on one side in the longitudinal direction of the curved portion 512, is provided on one side in the width direction of the symmetry axis line 510 (lower side in the drawing), and the conductor line 532 of the adjustment portion 53, which is formed continuously with the end portion on the other side in the longitudinal direction of the curved portion 512, is provided on the other side in the width direction of the symmetry axis line 510 (upper side in the drawing).

With this configuration of the first detection coil 5, the direction of the induced voltage generated in one side portion 51A, which is the portion on one side in the longitudinal direction than the center portion 51C in the detection portion 51, and the direction of the induced voltage generated in the adjustment portion 52, which is provided on one side in the longitudinal direction than the detection portion 51, are opposite. The direction of the induced voltage generated in the other side portion 51B, which is the portion on the other side in the longitudinal direction than the center portion 51C in the detection portion 51, and the direction of the induced voltage generated in the adjustment portion 53, which is provided on the other side in the longitudinal direction than the detection portion 51, are opposite.

In FIG. 5A, when the intensity of the magnetic field in the direction from the front to the back in the drawing gradually increases, the direction of the current that can be generated in the curved portions 511, 512 of the detection portion 51, the conductor lines 521, 522 of the adjustment portion 52, and the conductor lines 531, 532 of the adjustment portion 53 by this change in intensity of the magnetic field are indicated by arrows A₅₁, A₅₂, and A₅₃, respectively. If the target 2 is not attached to the rack shaft 13 and the symmetry axis line 510 and the central axis line C of the rack shaft 13 are parallel, the induced voltage generated in the one side portion 51A and the induced voltage generated in the other side portion 51B will balance and cancel each other, and the induced voltage generated at the adjustment portion 52 on one side in the longitudinal direction and the induced voltage generated at the adjustment portion 53 on the other side in the longitudinal direction will balance and cancel each other, no current flows in the first detection coil 5.

In the present embodiment, a maximum width W₅₁ of the detection portion 51 and maximum widths W₅₂, W₅₃ of the adjustment portions 52, 53 in the width direction of the substrate 3 are equivalent. More specifically, the maximum widths W₅₂, W₅₃ of the adjustment portions 52, 53 are 95% or more and 105% or less of the maximum width W₅₁ of the detection portion 51. This configuration contributes to downsizing the substrate 3 by effectively utilizing the space of the substrate 3 on one side in the longitudinal direction and the other side in the longitudinal direction of the detection portion 51 as space for the adjustment portions 52, 53. An open space is provided between the pair of short side portions 43, 44 of the excitation coil 4 and the adjustment portions 52, 53 to suppress the magnetic field generated by the current flowing in the short side portions 43, 44 from affecting the induced voltage generated in the adjustment portions 52, 53.

(Configuration of the Second Detection Coil 6) The second detection coil 6 has a detection portion 61 that faces the target 2 while the rack shaft 13 moves from one axial moving end to the other axial moving end, and a connection line portion 62 for connection with the input/output section 36. The position and length of the detection portion 61 in the longitudinal direction of the substrate 3 is the same as the position and length of the detection portion 51 of the first detection coil 5, and the detection portion 61 of the second detection coil 6 and the detection portion 51 of the first detection coil 5 overlap in the thickness direction of the substrate 3.

The detection portion 61 comprises a pair of curved portions 611, 612 symmetrical in the width direction of the substrate 3 across a symmetry axis line 610 extending in the longitudinal direction of the substrate 3, straight portions 613, 614 extending from an end portion on one side in the axial direction at each of the curved portions 611, 612 toward the symmetry axis line 610 along the width direction of the substrate 3, and straight portions 615, 616 extending from an end portion on the other side in the axial direction at each of the curved portions 611, 612 toward the symmetry axis line 610 along the width direction of the substrate 3. The curved portion 611 and the straight portions 613, 615 are formed in the second wiring layer 32. The curved portion 612 and the straight portions 614, 616 are formed in the fourth wiring layer 34.

The pair of curved portions 611, 612 are sine wave-shaped conductor lines that are symmetrical in the width direction of the substrate 3 across the symmetry axis line 610 that extends in the longitudinal direction of the substrate 3 and the detection portion 61. More specifically, the shape of the curved portion 611 in the second wiring layer 32 viewed from the normal direction of the substrate 3 is a cosine wave shape from 0° to 360° when the symmetry axis line 610 is regarded as the phase axis, as shown in FIG. 4B, and the shape of the curved portion 612 in the fourth wiring layer 34 viewed from the normal direction of the substrate 3 is a cosine wave shape from −180° to 180° when the symmetry axis line 610 is regarded as the phase axis, as shown in FIG. 4D. The pair of curved portions 611, 612 cross at two longitudinal intersections 601, 602 in the detection portion 61. The straight portion 615 of the second wiring layer 32 and the straight portion 616 of the fourth wiring layer 34 extending from the end portion on the other end in the axial direction of the pair of curved portions 611, 612 are connected by the via 35.

The connection line portion 62 connects the end portions on one side in the axial direction of the pair of curved portions 611 and 612 to the input/output section 36. In the present embodiment, the conductor line 621 connecting the end portion on one side in the longitudinal direction at the curved portion 611 to the second through-hole land 362 and the conductor line 622 connecting the end portion on one side in the longitudinal direction at the curved portion 612 to the third through-hole land 363 constitute the connection line portion 62. The conductor line 621 is formed in the second wiring layer 32 along the symmetry axis line 610. The conductor line 622 is formed in the fourth wiring layer 34 mainly along the symmetry axis line 610, but the portion intersecting the short side portion 43 of the excitation coil 4 is formed in the third wiring layer 33 via a plurality of vias 35.

The first detection coil 5 and the second detection coil 6 output an output signal, which is the voltage induced by the AC magnetic field generated by the excitation coil 4, to the calculation unit 8 via the connector 91 and the cable 92. The calculation unit 8 calculates the position of the target 2 based on this output signal and transmits the calculation results to the steering controller 19. The peak values of the voltages induced in the first detection coil 5 and the second detection coil 6 vary within a range of one cycle or less while the rack shaft 13 moves from one axial moving end to the other axial moving end. This enables the stroke sensor 1 to detect the absolute position of the rack shaft 13 over the entire range R₁ in which the rack shaft 13 can move in the axial direction.

### (Operation of Stroke Sensor 1)

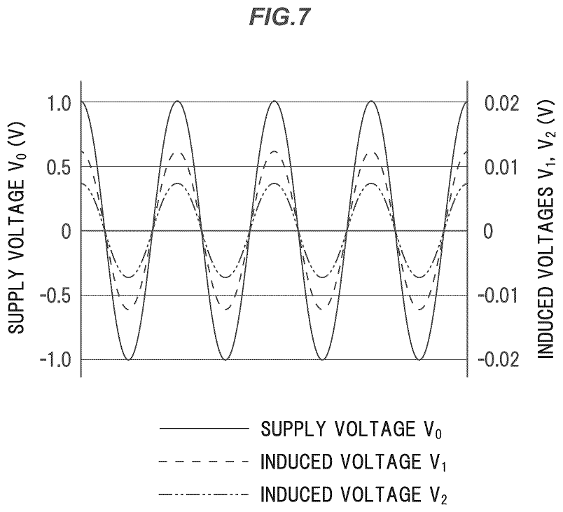

Next, the operation of the stroke sensor 1 for detecting the position of the target 2 with respect to the substrate 3 will be explained with reference to FIGS. 7 to 9. In the following explanation, the position of the target 2 refers to the position of the center point 20 (see FIG. 3) of the facing surface 2a in the axial direction. The overlap of the first detection coil 5 and the second detection coil 6 and the target 2 means that the first detection coil 5 and the second detection coil 6 and the target 2 are aligned along the normal direction of the substrate 3.

FIG. 7 is a graph showing an example of the relationship between the supply voltage V₀ supplied to the excitation coil 4 from the power supply unit 7, the induced voltage V₁ induced in the first detection coil 5, and the induced voltage V₂ induced in the second detection coil 6, when the target 2 overlaps the detection portions 51, 61 of the first detection coil 5 and the second detection coil 6. The horizontal axis of the graph in FIG. 7 represents time, and the supply voltage V₀ and the induced voltages V₁ and V₂ are shown in the vertical axes on the left and on the right respectively.

In the example shown in FIG. 7, the supply voltage V₀ and the induced voltages V₁ and V₂ are in the same phase, but the induced voltage V₁ induced in the first detection coil 5 switches between the same phase and the opposite phase each time the target 2 passes through the center portion 51C of the detection portion 51 of the first detection coil 5. The induced voltage V₂ induced in the second detection coil 6 switches between the same phase and the opposite phase each time the target 2 passes through the intersections 601, 602 where a pair of the curved portions 611, 612 cross. A high-frequency AC voltage of about 1 MHz to 1 GHz, for example, is supplied to the excitation coil 4 as the supply voltage V₀.

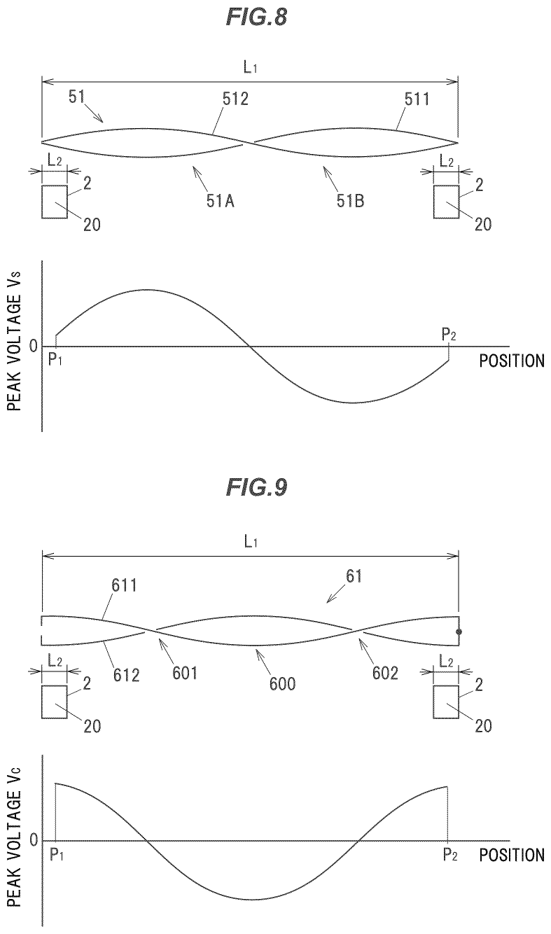

FIG. 8 is a graph showing the relationship between the peak voltage V_{S} which is the peak value of the induced voltage V₁ induced in the first detection coil 5, and the position of the target 2. FIG. 9 is an explanatory diagram schematically showing the relationship between the peak voltage V_{C}, which is the peak value of the induced voltage V₂ induced in the second detection coil 6, and the position of the target 2. In the graphs of peak voltages V_{S} and V_{C} shown in FIGS. 8 and 9, the position of the target 2 is shown on the horizontal axis.

The stroke sensor 1 can detect the absolute position of the target 2 in the axial direction of the rack shaft 13 to the extent that the entire axial length of the target 2 overlaps the detection portions 51, 61 of the first and second detection coils 5 and 6. In the graphs shown in FIGS. 8 and 9, the horizontal axis coordinate of the target 2 when the rack shaft 13 is at one axial moving end is P1, and the horizontal axis coordinate of the target 2 when the rack shaft 13 is at the other axial moving end is P2. The peak voltages V_{S} and V_{C} at each position are shown.

In the graphs shown in FIGS. 8 and 9, the peak voltage V_{S} of the first detection coil 5 is a positive value when the induced voltage V₁ induced in the first detection coil 5 is in phase with the supply voltage V₀ supplied to the excitation coil 4 and a negative value when it is in the opposite phase. Similarly, the peak voltage V_{C} of the second detection coil 6 shall be positive when the induced voltage V₂ induced in the second detection coil 6 is in phase with the supply voltage V₀ supplied to the excitation coil 4, and negative when it is in the opposite phase.

If ωx is defined as in formula [1], the peak voltages V_{S} and V_{C} are obtained by formulas [2] and [3], respectively, with Xp as the coordinate value of the abscissa coordinate of the target 2 in the graphs shown in FIGS. 8 and 9. In formula [1], L₁ is the longitudinal length of the detection portions 51, 61 of the first and second detection coils 5 and 6. In formulas [2] and [3], A is a predetermined constant and L₂ is the axial length of the target 2.

$$\begin{matrix}[ Formula 1 ] & \\ {ω}_{x} = \frac{2 π}{{L}_{1}} & [ 1 ]\end{matrix}$$

$$\begin{matrix}[ Formula 2 ] & \\ Vs = A sin \{ ( {ω}_{x} ( {X}_{p} - {L}_{2} ) \} & [ 2 ]\end{matrix}$$

$$\begin{matrix}[ Formula 3 ] & \\ Vc = A cos \{ ( {ω}_{x} ( {X}_{p} - {L}_{2} ) \} & [ 3 ]\end{matrix}$$

From formula [2] and formula [3], the coordinate value Xp of the target 2 in the graphs shown in FIGS. 8 and 9 can be obtained by formula [4]. In other words, the calculation unit 8 can calculate the position of the target 2 based on the peak voltages V_{S} and V_{C} by arithmetic operation.

$$\begin{matrix}[ Formula 4 ] & \\ {X}_{p} = \frac{arctan ( \frac{Vs}{Vc} )}{{ω}_{x}} + {L}_{2} & [ 4 ]\end{matrix}$$

### (Function and Effect of the Adjustment Portions 52, 53 of the Detection Coil 5)

For example, if the rack shaft 13 tilts against the substrate 3 due to vibration during vehicle travel and the distance between each part of the substrate 3 and the rack shaft 13 changes, the degree to which the rack shaft 13 affects the intensity distribution of the magnetic flux inside the excitation coil 4 will vary with the longitudinal position of the substrate 3. In the present embodiment, the effect of the inclination of the rack shaft 13 on the detection accuracy of the position of the target 2 is suppressed by the adjustment portions 52, 53 of the first detection coil 5. The function and effects of the adjustment portions 52, 53 will now be explained by comparison with a comparative example.

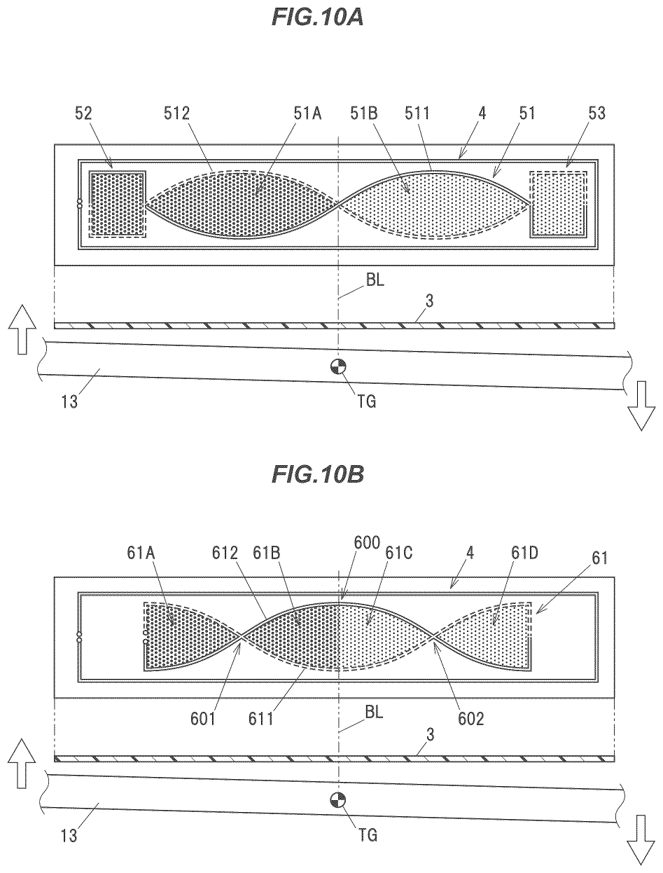

FIG. 10A is an explanatory diagram schematically showing the relationship between the inclination of the rack shaft 13 relative to the substrate 3 and the effect of the inclination of the rack shaft 13 on the magnetic flux density interlinked with the first detection coil 5. FIG. 10B is an explanatory diagram schematically showing the relationship between the inclination of the rack shaft 13 relative to the substrate 3 and the effect of the inclination of the rack shaft 13 on the magnetic flux density interlinked with the second detection coil 6. In FIGS. 10A and 10B, the bisector lines BL of the detection portions 51 and 61 of the first and second detection coils 5 and 6 are shown as two dotted chains, and the rack shaft 13 is tilted in the vertical direction in the drawing around the point indicated by the target mark TM on this bisector line BL. The rack shaft 13 is tilted in such a manner that the portion on the left side of the target mark TM is closer to the substrate 3 and the portion on the right side of the target mark TM is further away from the substrate 3. In FIGS. 10A and 10B, the inclination of the rack shaft 13 is shown in an exaggerated manner.

Eddy currents flow in the rack shaft 13 due to the magnetic flux of the alternating magnetic field generated by the excitation coil 4 and interlinked together. This eddy current acts to weaken the magnetic flux interlinked with the first and second detection coils 5 and 6. The effect of this action is greater in areas where the distance between the rack shaft 13 and the substrate 3 is closer. In FIGS. 10A and 10B, the areas inside the first and second detection coils 5 and 6 where this effect increases as the rack shaft 13 tilts are shown in dark gray, and the areas inside the first and second detection coils 5 and 6 where this effect decreases as the rack shaft 13 tilts are shown in light gray.

As shown in FIG. 10A, in the one side portion 51A and the adjustment portion 52 in the detection portion 51 of the first detection coil 5, the influence of the eddy currents generated in the rack shaft 13 becomes larger and the magnetic flux density becomes lower as the rack shaft 13 tilts as shown. This effect is greater in the adjustment portion 52, which is located farther from the bisector line BL, than in the one side portion 51A of the detection portion 51. In the other side portion 51B and the adjustment portion 53 in the detection portion 51 of the first detection coil 5, the influence of the eddy currents generated in the rack shaft 13 is smaller and the magnetic flux density is higher because the rack shaft 13 is tilted as shown in FIG. 10A. This effect is greater in the adjustment portion 53, which is located farther from the bisector line BL, than in the other side portion 51B of the detection portion 51.

However, the sum of the change in the induced voltage V₁ of the first detection coil 5 due to a lower magnetic flux density in the one side portion 51A of the detection portion 51 and the change in the induced voltage V₁ of the first detection coil 5 due to a higher magnetic flux density in the other side portion 51B of the detection portion 51 and the change in the induced voltage V of the first detection coil 5 due to a lower magnetic flux density in the adjustment portion 52, and the sum of the change in the induced voltage V₁ of the first detection coil 5 due to the lower magnetic flux density in the adjustment portion 52 and the change in the induced voltage V₁ of the first detection coil 5 due to the higher magnetic flux density in the adjustment portion 53 cancel each other. This can increase the detection accuracy of the position of the target 2, i.e., the position of the rack shaft 13.

The effect of the change in magnetic flux density due to the tilting of the rack shaft 13 with respect to the substrate 3 is greater in the adjustment portions 52, 53 than in the one side portions 51A and 51B of the detection portion 51. Therefore, when the maximum width W₅₁ of the detection portion 51 in the width direction of the substrate 3 and the maximum widths W₅₂, W₅₃ of the adjustment portions 52, 53 are equivalent, even if the length L₅₂ of the adjustment portion 52 in the longitudinal direction of the substrate 3 is shorter than the length L_{51A} of the one side portion 51A of the first detection coil 5 and the length L₅₃ of the adjustment portion 53 in the longitudinal direction of the substrate 3 is shorter than the length L_{51B} of the other side portion 51B of the first detection coil 5, the change in the induced voltage V₁ of the first detection coil 5 due to the change in the magnetic flux density in the one side portion 51A and the other side portion 51B of the detection portion 51 due to the inclination of the rack shaft 13 and the change in the induced voltage V₁ of the first detection coil 5 due to the change in the magnetic flux density in the adjustment portions 52, 53 can be offset.

Geometric analysis considering the change in magnetic flux density due to the inclination of the rack shaft 13 with respect to the substrate 3 shows the following. When the maximum width W₅₁ of the detection portion 51 in the width direction of the substrate 3 and the maximum widths W₅₂, W₅₃ of the adjustment portions 52, 53 are the same, if the respective lengths L₅₂, L₅₃ of the adjustment portions 52, 53 in the longitudinal direction of the substrate 3 are 14% of the length L₁ (L₁=L_{51A}+L_{51B}) of the detection portions 51, 61 in the longitudinal direction of the first detection coil 5, the change in the induced voltage V₁ of the first detection coil 5 due to an increase or decrease in the magnetic flux density in the one side portion 51A and the other side portion 51B of the detection portion 51 becomes equal to the change in the induced voltage V₁ of the first detection coil 5 due to an increase or decrease in the magnetic flux density in the adjustment portions 52, 53. Therefore, even if the rack shaft 13 is tilted with respect to the substrate 3, the induced voltage V₁ does not vary due to such an inclination.

For the second detection coil 6, due to its configuration, the change in the induced voltage V₂ is suppressed even if the rack shaft 13 is tilted with respect to the substrate 3. As shown in FIG. 10B, when an inner region of the detection portion 61 of the second detection coil 6 is divided in the longitudinal direction into a first compartment 61A, a second compartment 61B, a third compartment 61C, and a fourth compartment 61D, the effect of the magnetic flux density change caused by the inclination of the rack shaft 13 on the induced voltage V₂ is cancelled out by the second compartment 61B and the third compartment 61C as well as by the first compartment 61A and the fourth compartment 61D. Here, the first compartment 61A is the region closer to one side in the longitudinal direction than the intersection 601. The second compartment 61B is the region between the central portion 600 and the intersection 601 in the longitudinal direction of the detection portion 61. The third compartment 61C is the region between the central portion 600 and the intersection 602. The fourth compartment 61D is the region closer to the other side in the longitudinal direction than the intersection 602.

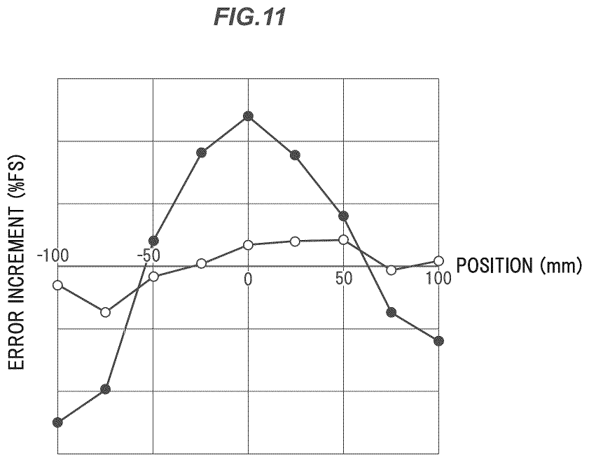

FIG. 11 is a graph showing the increment in detection error of the position of the target 2 due to the tilt of the rack shaft 13 with respect to the substrate 3 for the case where the first detection coil 5 has the adjustment portions 52, 53 and the case where the first detection coil 5 does not have the adjustment portions 52, 53. The horizontal axis of this graph shows the position of the target 2 on the − side (one side of the axial direction) and the + side (the other side of the axial direction) with the position of the target 2 when the rack shaft 13 is in the neutral position being 0 mm. The vertical axis represents the increment in detection error of the position of the target 2 due to a 0.5° tilt of the rack shaft 13 in % FS (FS means full scale). The black circle (•) in the graph is the result of the evaluation when the first detection coil 5 does not have the adjustment portions 52, 53. The white circle (∘) in the graph is the evaluation result when the first detection coil 5 has the adjustment portions 52, 53. The adjustment portions 52, 53 to be evaluated have the maximum widths W₅₂, W₅₃ the same as the maximum width W₅₁ of the detection portion 51, and the longitudinal lengths L₅₂, L₅₃ are 14% of the longitudinal length L₁ of the detection portions 51, 61 of the first detection coil 5.

As shown in FIG. 11, the error in the position of the target 2 is greatly reduced by the first detection coil 5 having the adjustment portions 52, 53.

### [First Modified Example of the Adjustment Portions 52, 53]

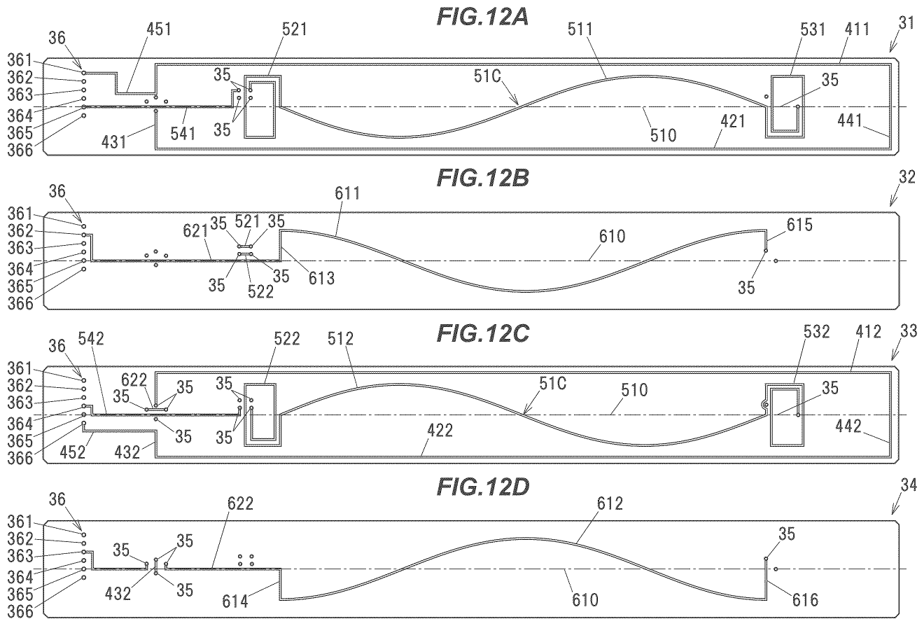

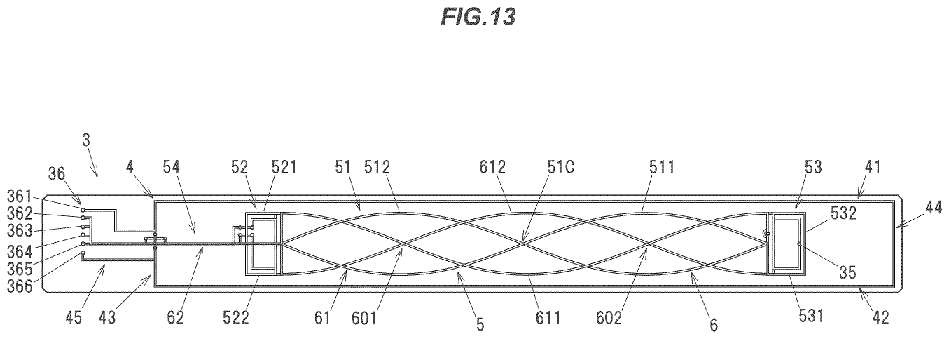

Next, the first modified example of the adjustment portions 52, 53 will be described with reference to FIGS. 12A to 12D and 13. FIGS. 12A to 12D are explanatory diagrams showing the wiring patterns of the first wiring layer 31, the second wiring layer 32, the third wiring layer 33, and the fourth wiring layer 34 of the substrate 3 on which the adjustment portions 52, 53 in the first modified example are formed. FIG. 13 is an explanatory diagram showing the first wiring layer 31, the second wiring layer 32, the third wiring layer 33, and the fourth wiring layer 34, as shown in FIGS. 12A to 12D overlaid on each other.

In the above embodiment, the case in which the adjustment portions 52, 53 each have one turn is described, but in the first modified example, the adjustment portions 52, 53 each have three turns. More precisely, the conductor lines 521 and 522, which constitute the adjustment portion 52, and the conductor lines 531 and 532, which constitute adjustment portion 53, each have 1.5 turns, thereby constituting adjustment portions 52, 53 with three turns.

According to this first modified example, in addition to the effects of the above embodiment, the length of the adjustment portions 52, 53 in the longitudinal direction of the substrate 3 can be shorter than in the above embodiment, making it possible to make the substrate 3 smaller.

### [Second Modified Example of the Adjustment Portions 52, 53]

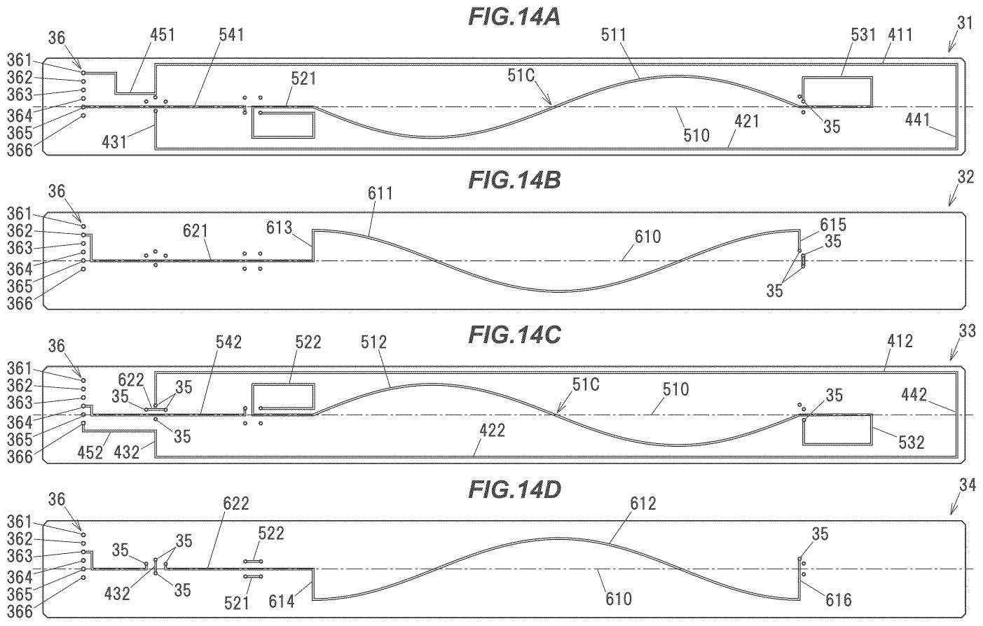

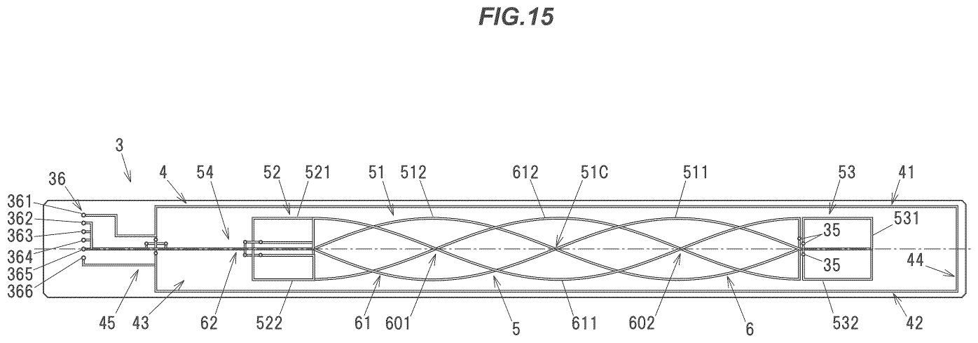

Next, the second modified example of the adjustment portions 52, 53 will be described with reference to FIGS. 14A to 14D and 15. FIGS. 14A to 14D are explanatory diagrams showing the wiring patterns of the first wiring layer 31, the second wiring layer 32, the third wiring layer 33, and the fourth wiring layer 34 of the substrate 3 on which the adjustment portions 52, 53 in the second modified example are formed. FIG. 15 is an explanatory diagram showing the first wiring layer 31, the second wiring layer 32, the third wiring layer 33, and the fourth wiring layer 34, as shown in FIGS. 14A to 14D overlaid on each other.

The example configuration of the adjustment portions 52, 53 described with reference to FIGS. 4A to 4D and 5 in the above embodiment shows the case in which the conductor line 521 of the adjustment portion 52 formed continuously with the end portion on one side in the longitudinal direction of the curved portion 511 constituting the detection portion 51 and the conductor line 532 of the adjustment portion 53 formed continuously with the end portion on the other side in the longitudinal direction of the curved portion 512 constituting the detection portion 51 are formed on the other side (upper side in the drawing) in the width direction of the symmetry axis line 510, while the conductor line 531 of the adjustment portion 53 formed continuously with the end portion on the other side in the longitudinal direction of the curved portion 511 constituting the detection portion and the conductor line 522 of the adjustment portion 52 formed continuously with the end portion on the one side in the longitudinal direction of the curved portion 512 constituting the detection portion 51 are formed on one side (lower side in the drawing) in the width direction of the symmetry axis line 510. In the second modified example, the arrangement of the conductor lines 521, 522, 531, 532 of the adjustment portions 52, 53 in the width direction of the substrate 3 is the opposite of the above embodiment. Also, the way the conductor lines 521, 522, 531, 532 go around when viewed by tracing from the curved portions 511, 512 is the opposite of the above embodiment.

This second modified example also produces the same effect as the above embodiment by the same function.

### Summary of Embodiment

Next, technical ideas understood from the above embodiment, are described with reference to the reference numerals and the like used in the embodiment. However, each reference numeral in the following description does not limit the constituent elements in the scope of claims to the members and the like specifically shown in the embodiment.

According to the first feature, a position detection device 1 for detecting a position of a shaft (rack shaft 13) made of metal that moves forward and backward in an axial direction within a predetermined range includes an excitation coil 4 that generates an alternating magnetic field; a target which moves integrally with the shaft and in which a magnetic flux of the alternating magnetic field is interlinked; and a detection coil 5 having a detection portion 51 which faces the target 2 while the shaft 13 moves from one axial moving end to an other axial moving end, wherein an induced voltage induced in the detection portion 51 by the magnetic flux of the alternating magnetic field varies with a position of the target 2 relative to the detection portion 51, and wherein the detection coil 5 has adjustment portions 52, 53 that suppress an effect of an inclination of the shaft 13 with respect to the detection portion 51 on the induced voltage induced in the detection portion 51.

According to the second feature, in the position detection device 1 as described in the first feature, the detection portion 51 extends in a longitudinal direction along an axial direction of the shaft 13 and the adjustment portions 52, 53 are provided on both sides of the detection portion 51 in the longitudinal direction.

According to the third feature, in the position detection device 1 as described in the second feature, the detection portion 51 has a shape combining a pair of curved portions 511, 512 symmetrical across a symmetry axis line extending the longitudinal direction, the pair of curved portions 511, 512 crossing at a center portion 51C in the longitudinal direction of the detection portion 51, a direction of the induced voltage generated in a portion 51A closer to one side in the longitudinal direction than the center portion 51C in the detection portion 51 is opposite to a direction of the induced voltage generated in the adjustment portions 52, 53 closer to the one side in the longitudinal direction than the detection portion 51, and a direction of the induced voltage generated in a portion 51B closer to an other side in the longitudinal direction than the detection portion 51 is opposite to a direction of the induced voltage generated in the adjustment portions 52, 53 closer to the other side in the longitudinal direction than the detection portion 51.

According to the fourth feature, in the position detection device 1 as described in the third feature, a maximum width W₅₁ of the detection portion 51 and maximum widths W₅₂, W₅₃ of the adjustment portions 52, 53 in a width direction perpendicular to the longitudinal direction are equivalent.

According to the fifth feature, in the position detection device 1 as described in any one of the first feature to the fourth feature, the excitation coil 4 and the detection coil 5 are formed on a single substrate 3.

According to the sixth feature, in the position detection device 1 as described in the fifth feature, a second detection coil 6 having a shape combining a pair of curved portions 611, 612 is formed on the substrate 3, and a phase of change in magnitude of an induced voltage induced in the second detection coil 6 while the shaft 13 moves from the one axial moving end to the other axial moving end is 90° different from a phase of change in magnitude of the induced voltage induced in the detection coil 5.

According to the seventh feature, in the position detection device 1 as described in the first feature, the shaft 13 is a rack shaft 13 of a steering device 10 of a vehicle.

That is all for the description of the embodiment of the present invention, but the above embodiment does not limit the invention according to the scope of claims. It should be noted that not all combinations of features are essential to the means for solving problems of the invention. Additionally, the present invention may be implemented by modifying it, as appropriate, without departing from the scope and spirit of the invention. For example, the following modifications can be made.

The above embodiment describes a case in which the first and second detection coils 5, 6 are sine wave-shaped is described, but it is not limited to this case, for example, they may be triangular wave-shaped. The excitation coil 4 and the first and second detection coils 5, 6 need not necessarily be formed on a single substrate. Furthermore, in the above embodiment, the case in which the target of position detection by the stroke sensor 1 is a rack shaft of a steering device is described, but the detection object of the present invention is not limited to a rack shaft, and can be applied to the detection of the position of a metal shaft that moves axially forward and backward.

1. A position detection device for detecting a position of a shaft made of metal that moves forward and backward in an axial direction within a predetermined range, comprising:
an excitation coil that generates an alternating magnetic field;
a target that moves integrally with the shaft and in which a magnetic flux of the alternating magnetic field is interlinked; and
a detection coil having a detection portion that faces the target while the shaft moves from one axial moving end to an other axial moving end,
wherein an induced voltage induced in the detection portion by the magnetic flux of the alternating magnetic field varies with a position of the target relative to the detection portion, and
wherein the detection coil has adjustment portions that suppress an effect of an inclination of the shaft with respect to the detection portion on the induced voltage induced in the detection portion.

2. The position detection device, according to claim 1, wherein the detection portion extends in a longitudinal direction along an axial direction of the shaft, and
wherein the adjustment portions are provided on both sides of the detection portion in the longitudinal direction.

3. The position detection device, according to claim 2, wherein the detection portion has a shape combining a pair of curved portions symmetrical across a symmetry axis line extending the longitudinal direction,
wherein the pair of curved portions crossing at a center portion in the longitudinal direction of the detection portion,
wherein a direction of the induced voltage generated in a portion closer to one side in the longitudinal direction than the center portion in the detection portion is opposite to a direction of the induced voltage generated in the adjustment portions closer to the one side in the longitudinal direction than the detection portion, and
wherein a direction of the induced voltage generated in a portion closer to an other side in the longitudinal direction than the detection portion is opposite to a direction of the induced voltage generated in the adjustment portions closer to the other side in the longitudinal direction than the detection portion.

4. The position detection device, according to claim 3, wherein a maximum width of the detection portion and maximum widths of the adjustment portions in a width direction perpendicular to the longitudinal direction are equivalent.

5. The position detection, according to claim 1, wherein the excitation coil and the detection coil are formed on a single substrate.

6. The position detection device, according to claim 5, wherein a second detection coil having a shape combining a pair of curved portions is formed on the substrate, and
wherein a phase of change in magnitude of an induced voltage induced in the second detection coil while the shaft moves from the one axial moving end to the other axial moving end is 90° different from a phase of change in magnitude of the induced voltage induced in the detection coil.

7. The position detection device, according to claim 1, wherein the shaft is a rack shaft of a steering device of a vehicle.
